(19) United States
(12) Patent Application Publication
(10) Pub. No.: US 2007/0074851 A1
(43) Pub. Date: Apr. 5, 2007

(54) Heat sink

(75) Inventor: Shu-Ju Lin, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/393,118

(22) Filed: Mar. 29, 2006

(30) Foreign Application Priority Data
Oct. 5, 2005 (TW) 094217203

(51) Int. Cl. H05K 7/20

(52) U.S. Cl. 165/80.3; 361/705; 165/185

(57) ABSTRACT

A heat sink includes a base, a set of fins and at least an elastic fixing member mounted on a surface of the base. The elastic fixing member includes an elastic sheet mounted on the base, a supporting portion disposed on the elastic sheet and a fixing portion disposed on the supporting portion. The heat sink is secured to a printed circuit board through the fixing portion of the elastic fixing member, with the base of the heat sink being in direct contact with a heat generating component mounted on the printed circuit board. The distance between the base of the heat sink and the heat generating component can be controlled so as to even pressure on the heat generating component and efficiently decrease heat stress.

### FIELD OF THE INVENTION

The present invention relates to heat sinks, and more particularly, to a heat sink for dissipating heat generated from a heat generating component, which is contacted with the heat sink.

### BACKGROUND OF THE INVENTION

It is well known that heat generating components in a computer such as central processing units, microprocessors or chipsets generate a large amount of heat during the computer operates. As the generated heat increases above a critical temperature, a failure can occur in the heat generating components. Therefore, the excess heat must be dissipated to prevent such failures.

Since a chipset is responsible for data transferring between primary chips and peripheral I/O components, it is particularly important to dissipate heat generated by the chipset. Usually, the chipset is in close contact with a heat sink for efficient heat dissipation. Such a heat sink is shown in FIG. 3 and FIG. 4.

As shown in FIG. 3, the heat sink includes a base 10 with a set of fins mounted thereon, and two fixing portions 20 disposed at lateral sides of the base 10. The base 10 is made of aluminum and the fixing portions 20 can be made of iron or aluminum alloy. As shown in FIG. 4, the heat sink is disposed on a printed circuit board 50 with the base 10 of the heat sink being in direct contact with the heat generating component 30 such as a chipset and the fixing portions 20 of the heat sink being passed through the printed circuit board 50. Then, soldering portions 40 are formed by soldering solder balls (not shown) at normal temperature to fix the fixing portions 20 to the printed circuit board 50.

However, during the soldering process, it may happen that pressures applied to the two fixing portions 20 are different from each other or excessive, which often causes uneven contact between the base 10 and the heat generating component 30, thereby resulting in such problems as cracks of the chip.

Meanwhile, during the operation of the computer, the heat generating component generates a large amount of heat and increases the surface temperature thereof. If the above method is used to fix the heat sink to the heat generating component, because the heat sink is made of different materials with different coefficients of thermal expansion, the heat stress is introduced, which can cause such problems as cracks of the soldering portions 40 and deformations of the printed circuit board 50, thereby decreasing reliability of products.

Furthermore, while inserting the fixing portions 20 to the corresponding inserting holes of the printed circuit board 50, the position and size of the fixing portions 20 and the inserting holes should be in the tolerance range. If the fixing portion 20 has a maximum value and the inserting hole has a minimum value in the tolerance range, the assembling process will become difficult and even impossible. Moreover, after fixing the heat sink to the printed circuit board 50, the base 10 of the heat sink directly presses against the heat generating component 30. If the base is deformed during the soldering process or by the heat stress, the heat generating component 30 is easy to be damaged by the base.

Accordingly, there is a need to develop a heat sink which can be uniformly attached to a heat generating component and efficiently decrease the heat stress.

### SUMMARY OF THE INVENTION

According to the above defects, an objective of the present invention is to provide a heat sink, which can be uniformly attached to a heat generating component.

Another objective of the present invention is to provide a heat sink, which can efficiently decrease heat stress.

A further objective of the present invention is to provide a heat sink, which can increase product reliability.

Still another objective of the present invention is to provide a heat sink, which can be easily assembled with a printed circuit board.

A further objective of the present invention is to provide a heat sink, which can prevent damaging the heat generating component.

To achieve the above and other objectives, the heat sink of the present invention comprises a base, a set of fins and at least an elastic fixing member mounted to the base, wherein the elastic fixing member comprises an elastic sheet mounted to the base of the heat sink, a supporting portion disposed on the elastic sheet and a fixing portion disposed on the supporting portion.

Preferably, the elastic sheet is of rectangular shape. The supporting portion is a pillar-shaped structure. The supporting portion may be disposed at a corner of the elastic sheet. The fixing portion may also be a pillar-shaped structure. Preferably, the heat sink comprises two elastic fixing members. In other preferred embodiment, the number of the elastic fixing members may be more than two. The heat sink may further comprise a stepped portion and a contact region. The stepped portion may be disposed in position corresponding to the elastic fixing member. The contact regionmay contact with a heat generating component such as a chipset. Further, the heat sink may comprise at least a soldering portion.

According to the present invention, the distance between the base of the heat sink and the heat generating component may be controlled through the elastic fixing member such that an even pressure may be applied on the heat generating component. Thus, such problems as cracks or damages of the chip resulted from uneven or excessive pressure during the soldering operation can be avoided. Further, as the design of the elastic fixing member can absorb the manufacturing tolerance, when the fixing portions is inserted into the inserting holes of the printed circuit board, the fixing portions can be slightly adjusted to facilitate the assembling process.

Meanwhile, the heat sink of the present invention can efficiently decrease heat stress resulted from different coefficients of thermal expansion of different materials, thereby avoiding such problems as cracks of the soldering portions and deformation of the printed circuit board.

### BRIEF DESCRIPTION OF DRAWINGS

FIG. 1 is a structural diagram of a heat sink according to a preferred embodiment of the present invention;

FIG. 2 is a diagram of a heat sink in use according to a preferred embodiment of the present invention;

FIG. 3 is a structural diagram of a conventional heat sink; and

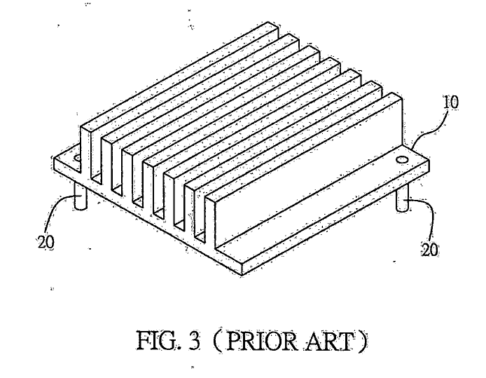

FIG. 4 is a diagram of a conventional heat sink in use.

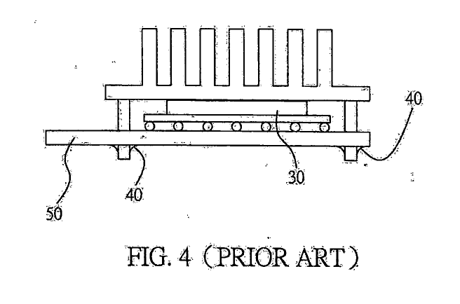

### DETAILED DESCRIPTION OF PREFERRED EMBODIMENTS

Hereunder, embodiments of the present invention will be described in full detail with reference to the accompanying drawings.

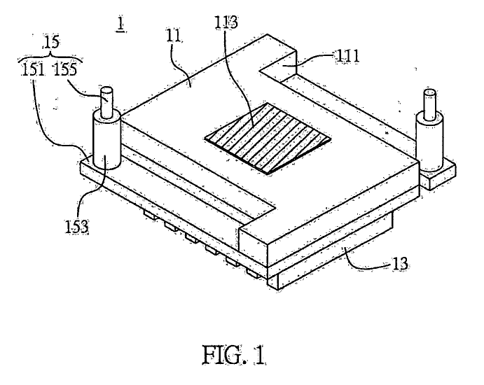

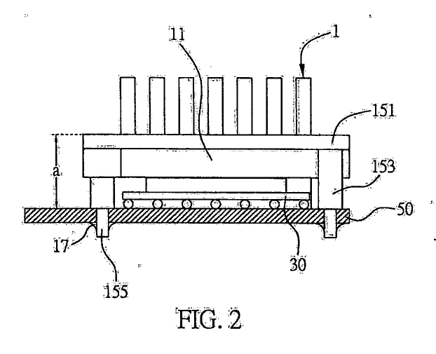

FIGS. 1 to 2 are diagrams of the heat sink according to a preferred embodiment of the present invention. The heat sink of the present invention can be directly attached to a heat generating component, such as a chipset, a central processing unit, a micro processing unit and so on. In the present embodiment, the heat generating component is a chipset.

Referring to FIG. 1, the heat sink 1 comprises a base 11, a set of fins 13 and two elastic fixing members 15 mounted to a surface of the base 11. Each of the elastic fixing members 15 comprises an elastic sheet 151, a supporting portion 153 disposed on the elastic sheet 151 and a fixing portion 155 disposed on the supporting portion 153.

The base 11 is a substantially rectangular-shaped conductive block, which can be made of aluminum, for example. Two L-shaped stepped portions 111 are respectively formed at two sides of the base 11 corresponding in position to the elastic fixing members 15. A rectangular contact region 113 is further formed substantially in the center of the base 11 for directly contacting a chipset.

It should be noted that the shape of the base 11, the stepped portions 111 and the contact region 113 is not limited to the present embodiment. For example, the stepped portions 111 can be of any other regular or irregular shape and the shape of the contact region 113 can be designed according to that of the heat generating component.

The fins 13 of sheet shape are spaced apart on the surface of the base 11. The fins 13 are used to increase the surface area such that heat generated from the heat generating component can be dissipated quickly. The fins 13 can be made of aluminum. It should be noted that the shape, number and arranging structure of the fins 13 can be modified in practical implementation. In addition, the base 11 and the fins 13 can be made of materials other than aluminum.

The elastic fixing members 15 are respectively disposed at two corners of the base 11. The elastic fixing members 15 are used for supporting the base 11 such that the base 11 can be located over and directly contacted with the heat generating component such as a chipset. Meanwhile, the elastic fixing members 15 are fixed to the printed circuit board with the heat generating component mounted thereon (not shown in FIG. 1), which is detailed later. It should be noted that the number and position of the elastic fixing members 15 are not limited to the present embodiment.

Each elastic sheet 151 of substantially rectangular shape is disposed on a surface of the base 11 that is opposed to the surface having the contact region 113. That is, the elastic sheet 151 is disposed far from the surface of the heat generating component such as a chipset. Each supporting portion 153 of pillar-shaped structure is disposed at a corner of the elastic sheet 151 for supporting the base 11 of the heat sink 1 on the printed circuit board (detailed later). Each fixing portion 155 also has pillar-shaped structure and the diameter of the fixing portion 155 is smaller than that of the supporting portion 153. The fixing portions 155 are respectively disposed on the supporting portions 153. The fixing portions 155 can be fixed to the printed circuit board for fixing the heat sink to the printed circuit board. It should be noted that the shape and position of the supporting portions 153 and the fixing portions 155 are not limited to the present embodiment.

The elastic fixing members 15 can be made of iron or aluminum alloy for increasing fixing intensity. But it is not limited thereto.

Referring to FIG. 2, soldering portions 17 are formed by soldering solder balls at normal temperature to fix the fixing portions 155 to the printed circuit board 50 such that the base 11 is in direct contact with the heat generating component 30, thereby efficiently dissipating heat generated from the heat generating component 30 during operation. The distance between the base 11 and the printed circuit board 50 is denoted as a.

In operation, the heat generating component 30 such as a chipset generates a lot of heat. The heat increases the temperature on the surface of the heat generating component 30. Because of elasticity of the elastic sheets 151, the elastic sheets 151 can self adjust its deformable degree. Meanwhile, the supporting portions 153 can keep a certain distance between the base 11 of the heat sink 1 and the printed circuit board 50. Thus, the base 11 can be uniformly attached to the heat generating component 30. Even though the heat sink is made of different materials of different coefficients of thermal expansion, the heat stress will not damage the heat sink and the printed circuit board. Therefore, the distance between the base 11 of the heat sink 1 and the printed circuit board 50 is kept at a and the base 11 is kept in contact with the heat generating component 30. Also, the soldering portions 17 and the printed circuit board 50 are not changed.

Accordingly, the present invention only needs to control the deformable degree of the elastic fixing members 15 (that is, elastic sheets 151) for controlling the distance a between the heat sink 1 and the printed circuit board 50 such that a uniform pressure can be applied on the heat generating component and the heat stress can be decreased in order to protect the heat generating component 30, the soldering portions 17 and the printed circuit board 50. It should be noted that the elastic sheets 151 can also be disposed on the surface of the base 11 having the contact region.

Further, the design of the elastic sheets 151 of the elastic fixing members 15 can absorb the tolerance such that the position of the fixing portions 155 can be slightly adjusted when the fixing portions 155 is inserted to the corresponding inserting holes of the printed circuit board 50. Moreover, by combining the elasticity of the elastic sheets 151 and distance limiting function of the supporting portions 153, the heat generating component 30 can be protected from being damaged by the heat sink which is deformed by the heat stress during the operation of the heat sink or during the soldering process.

Compared with the prior art, the present invention can keep a certain distance between the heat sink and the heat generating component such that a uniform pressure can be applied on the heat generating component. Meanwhile, the elastic fixing members of the present invention can efficiently decrease the heat stress to protect the soldering portions and the printed circuit board, thereby increasing the product reliability.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A heat sink comprising a base, a set of fins and at least an elastic fixing member, wherein the elastic fixing member comprises an elastic sheet mounted to the base, a supporting portion disposed on the elastic sheet and a fixing portion disposed on the supporting portion.

2. The heat sink of claim 1, wherein the elastic sheet is rectangular-shaped.

3. The heat sink of claim 1, wherein the supporting portion has a pillar-shaped structure.

4. The heat sink of claim 1, wherein the supporting portion is disposed at a corner of the elastic sheet.

5. The heat sink of claim 1, wherein the fixing portion has a pillar-shaped structure.

6. The heat sink of claim 1, wherein the heat sink comprises two elastic fixing members.

7. The heat sink of claim 1, wherein the base of the heat sink further comprises a stepped portion.

8. The heat sink of claim 1, wherein the base of the heat sink further comprises a contact region.

9. The heat sink of claim 8, wherein the contact region is rectangular-shaped.

10. The heat sink of claim 1, wherein the heat sink further comprises a soldering portion.

11. The heat sink of claim 1, wherein the supporting portion is a pillar-shaped structure that is larger than the supporting portion.
